(19) United States
(12) Patent Application Publication
(10) Pub. No.: US 2011/0139248 A1
(43) Pub. Date: Jun. 16, 2011

(54) QUANTUM DOT SOLAR CELLS AND METHODS FOR MANUFACTURING SOLAR CELLS

(75) Inventors: Anna Liu, Shanghai (CN); Zhi Zheng, Shanghai (CN); Linan Zhao, Shanghai (CN); Marilyn Wang, Shanghai (CN)

(73) Assignee: Honeywell International Inc., Morristown, NJ (US)

(21) Appl. No.: 12/690,777

(22) Filed: Jan. 20, 2010

Related U.S. Application Data
(63) Continuation-in-part of application No. 12/636,402, filed on Dec. 11, 2009.

(51) Int. Cl. H01L 31/0272; H01L 21/04; H01L 31/18; H01L 31/0216

(52) U.S. Cl. 136/260; 438/500; 438/69; 977/774; 257/E21.04; 257/E31.12

(57) ABSTRACT

Solar cells, methods for manufacturing a quantum dot layer for a solar cell, and methods for manufacturing solar cells are disclosed. An example method for manufacturing a quantum dot layer for a solar cell includes providing an electron conductor layer, providing a quantum dot chemical bath deposition solution, controlling the temperature of the quantum dot chemical bath deposition solution to a temperature of about 30° C. or greater, and immersing the electron conductor layer in the quantum dot chemical bath deposition solution for about 1-10 hours. The quantum dot chemical bath deposition solution may include CdSe.

### CROSS-REFERENCE TO RELATED APPLICATIONS

This application is a continuation-in-part of U.S. patent application Ser. No. 12/636,402, filed Dec. 11, 2009 and entitled “QUANTUM DOT SOLAR CELL”, the entire disclosure of which is herein incorporated by reference.

### TECHNICAL FIELD

The disclosure relates generally to solar cells. More particularly, the disclosure relates to quantum dot solar cells.

### BACKGROUND

A wide variety of solar cells have been developed for converting sunlight into electricity. Of the known solar cells, each has certain advantages and disadvantages. There is an ongoing need to provide alternative solar cells as well as alternative methods for manufacturing solar cells.

### SUMMARY

The disclosure relates generally to solar cells, methods for manufacturing a quantum dot layer for a solar cell, and methods for manufacturing solar cells. An example method for manufacturing a quantum dot layer for a solar cell may include providing an electron conductor layer, providing a quantum dot chemical bath deposition solution, controlling the temperature of the quantum dot chemical bath deposition solution to a temperature from about 10° C. to 70° C., or lower or greater, and immersing the electron conductor layer in the quantum dot chemical bath deposition solution for about 0.5-10 hours. The quantum dot chemical bath deposition solution may include CdSe.

An example method for manufacturing a solar cell may include providing an electron conductor layer, providing a quantum dot chemical bath deposition solution, controlling the temperature of the quantum dot chemical bath deposition solution to a temperature from about 10° C. to 70° C., or lower or greater, immersing the electron conductor layer in the quantum dot chemical bath deposition solution for about 0.5-10 hours to form a quantum dot layer on the electron conductor layer, providing a hole conductor layer, and coupling the hole conductor layer to the quantum dot layer. The quantum dot chemical bath deposition solution may include CdSe.

An example solar cell may include an electron conductor layer and a hole conductor layer. A quantum dot layer may be disposed between the electron conductor layer and the hole conductor layer. The quantum dot layer may include a plurality of quantum dots having an average outer dimension greater than about 25 nanometers and that may be formed using a chemical bath deposition process at a temperature of about 30° C. or greater. The quantum dot layer may include CdSe.

The above summary is not intended to describe each and every disclosed embodiment or every implementation of the disclosure. The Figures and Description which follow more particularly exemplify certain illustrative embodiments.

### BRIEF DESCRIPTION OF THE DRAWINGS

The invention may be more completely understood in consideration of the following detailed description of various embodiments of the invention in connection with the accompanying drawings, in which:

FIG. 1 is a schematic cross-sectional side view of an illustrative but non-limiting example of a solar cell;

FIG. 2 is a schematic cross-sectional side view of another illustrative but non-limiting example of a solar cell;

FIG. 3 is a SEM image of an example layer of CdSe quantum dots;

FIG. 4 is a SEM image of another example layer of CdSe quantum dots;

FIG. 5 is a plot of absorption versus wavelength for various example quantum dot layers; and

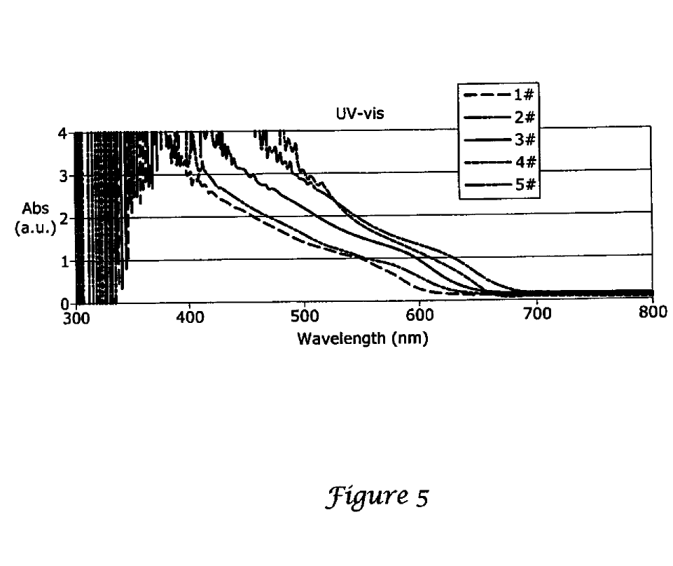

FIG. 6 is a plot of current (I) versus voltage (V) of various example quantum dot layers.

While the disclosure is amenable to various modifications and alternative forms, specifics thereof have been shown by way of example in the drawing and will be described in detail. It should be understood, however, that the intention is not to limit the invention to the particular embodiments or examples described. On the contrary, the intention is to cover all modifications, equivalents, and alternatives falling within the spirit and scope of the disclosure.

### DESCRIPTION

The following description should be read with reference to the drawings in which similar elements in different drawings are numbered the same. The drawings, which are not necessarily to scale, depict certain illustrative embodiments and are not intended to limit the scope of the invention.

For the following defined terms, these definitions shall be applied, unless a different definition is given in the claims or elsewhere in this specification.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

A wide variety of solar cells (which also may be known as photovoltaics and/or photovoltaic cells) have been developed for converting sunlight into electricity. Some example solar cells include a layer of crystalline silicon. Second and third generation solar cells often utilize a thin film of photovoltaic material (e.g., a “thin” film) deposited or otherwise provided on a substrate. These solar cells may be categorized according to the photovoltaic material deposited. For example, inorganic thin-film photovoltaics may include a thin film of amorphous silicon, microcrystalline silicon, CdS, CdTe, Cu₂S, copper indium diselenide (CIS), copper indium gallium diselenide (CIGS), etc. Organic thin-film photovoltaics may include a thin film of a polymer or polymers, bulk heterojunctions, ordered heterojunctions, a fullerence, a polymer/fullerence blend, photosynthetic materials, etc. These are only examples.

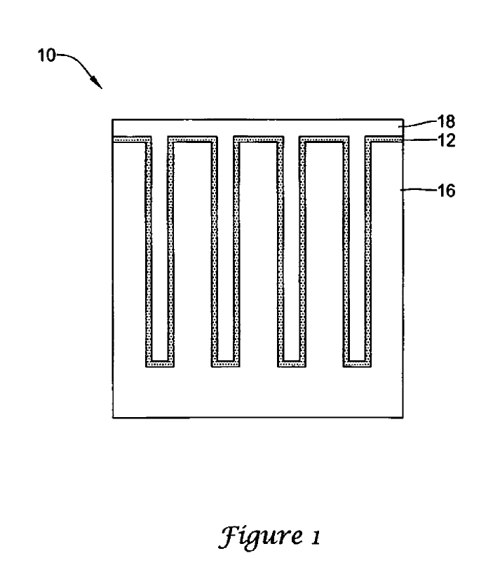

FIG. 1 is a schematic cross-sectional side view of an illustrative solar cell 10. In the illustrative example shown in FIG. 1, there may be a three-dimensional intermingling or interpenetration of the various layers forming solar cell 10, but this is not required. The illustrative solar cell 10 includes a quantum dot layer 12. Quantum dot layer 12 may be considered as representing a plurality of individual quantum dots. The illustrative solar cell 10 may also include an electron conductor layer 16. In some cases, electron conductor layer 16 may be an n-type conductor. While not required, a bifunctional ligand layer (not shown) may be disposed between electron conductor layer 16 and quantum dot layer 12. The bifunctional ligand layer may include a number of bifunctional ligands that are coupled to electron conductor layer 16 and to quantum dot layer 12. The illustrative solar cell 10 may further include a hole conductor layer 18. Hole conductor layer 18 may be a p-type conducting layer. In some cases, a first electrode (not explicitly shown) may be electrically coupled to the electron conductor layer 16, and a second electrode (not explicitly shown) may be coupled to the hole conductor layer 18, but this is not required in all embodiments. It is contemplated that solar cell 10 may include other structures, features and/or constructions, as desired.

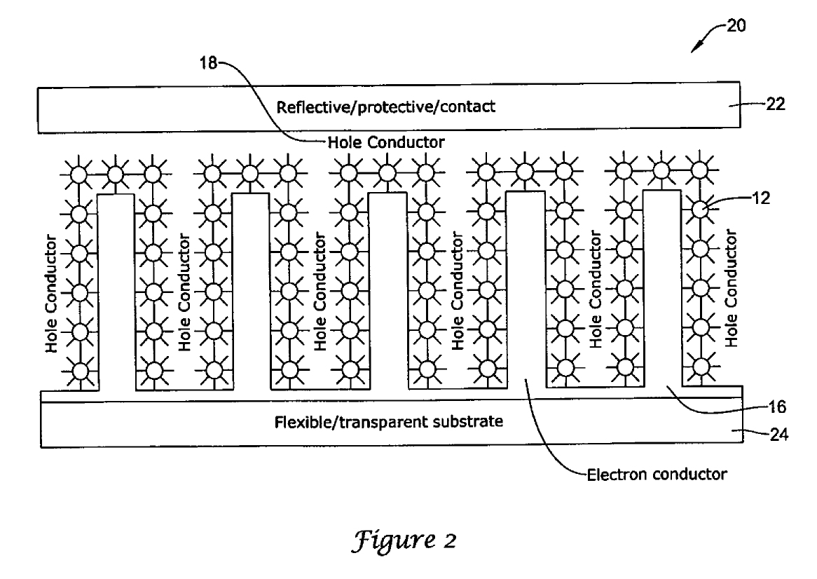

FIG. 2 is a schematic cross-sectional side view of an illustrative solar cell 20 that is similar to solar cell 10 (FIG. 1). In some cases, a reflective and/or protecting layer 22 may be disposed over the hole conductor layer 18, as shown. When layer 22 is reflective, light may enter the solar cell 20 from the bottom, e.g. through the flexible/transparent substrate 24. Some of the light may pass through the active layer 12, which may then be reflected back to the active layer 12 by the reflective layer 22, thereby increasing the efficiency of the solar cell 20. When provided, the reflective and/or protecting layer 22 may be a conductive layer, and in some cases, may act as the second electrode discussed above with respect to FIG. 1. In some instances, the reflective and/or protecting layer 22 may include a Pt/Au/C film as both catalyst and conductor, but this is not required. The reflective and/or protecting layer 22 is optional.

In some embodiments, solar cell 10 may include one or more substrates (e.g., substrates 22/24) and/or electrodes as is typical of solar cells. These structures may be made from a variety of materials including polymers, glass, and/or transparent materials polyethylene terephthalate, polyimide, low-iron glass, fluorine-doped tin oxide, indium tin oxide, Al-doped zinc oxide, a transparent conductive oxide, metal foils, Pt, other substrates coated with metal (e.g., Al, Au, etc.), any other suitable conductive inorganic element or compound, conductive polymer, and other electrically conductive material, or any other suitable material.

In the illustrative embodiment of FIG. 2, electron conductor layer 16 may be in electrical communication with the flexible and transparent substrate 24, but this is not required. A quantum dot layer 12 may be provided over the electron conductor layer, followed by a hole conductor layer 18 as discussed above. As noted above, there may be a three-dimensional intermingling or interpenetration of certain layers forming solar cell 20, but this is not required.

In some cases, the electron conductor layer 16 may be a metallic and/or semiconducting material, such as TiO₂ or ZnO. Alternatively, electron conductor layer 16 may be an electrically conducting polymer such as a polymer that has been doped to be electrically conducting and/or to improve its electrical conductivity. Electron conductor layer 16 may include an n-type conductor and/or form or otherwise be adjacent to the anode (negative electrode) of cell 20. In at least some embodiments, electron conductor layer 16 may be formed or otherwise include a structured pattern or array of, for example, nanoparticles, nanopillars, nanowires, or the like, as shown.

Hole conductor layer 18 may include a p-type conductor and/or form or otherwise be adjacent to the cathode (positive electrode) of cell 20. In some instances, hole conductor layer 18 may be a conductive polymer, but this is not required. The conductive polymer may, for example, be or otherwise include a functionalized polythiophene. An illustrative but non-limiting example of a suitable conductive polymer has

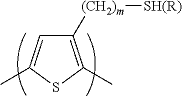

as a repeating unit, where R is absent or alkyl and m is an integer ranging from about 6 to about 12. The term “alkyl” refers to a straight or branched chain monovalent hydrocarbon radical having a specified number of carbon atoms. Examples of “alkyl” include, but are not limited to, methyl, ethyl, n-propyl, isopropyl, n-butyl, s-butyl, t-butyl, n-pentyl, n-hexyl, 3-methylpentyl, and the like.

Another illustrative but non-limiting example of a suitable conductive polymer has

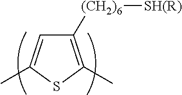

as a repeating unit, where R is absent or alkyl.

Another illustrative but non-limiting example of a suitable conductive polymer has

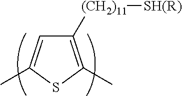

as a repeating unit, where R is absent or alkyl.

Another illustrative but non-limiting example of a suitable conductive polymer has

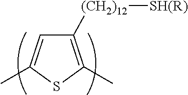

as a repeating unit, where R is absent or alkyl.

The quantum dot layer 12 may include a plurality of quantum dots. Quantum dots are typically very small semiconductors, having dimensions in the nanometer range. Because of their small size, quantum dots may exhibit quantum behaviors that are distinct from what would otherwise be expected from a larger sample of the material. In some cases, quantum dots may be considered as being crystals composed of materials from Groups II-VI, III-V, or IV-VI materials. The quantum dots employed herein may be formed using any appropriate technique. Examples of specific pairs of materials for forming quantum dots include, but are not limited to, MgO, MgS, MgSe, MgTe, CaO, CaS, CaSe, CaTe, SrO, SrS, SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs and InSb.

Forming such a quantum dot layer 12 may be accomplished using any number of processes, methods and/or techniques including, for example, a chemical bath deposition (CBD). For example, manufacturing quantum dot layer 12 may include providing a suitable substrate such as electron conductor layer 16. In some cases, electron conductor layer 16 may be immersed in NH₄F for a few minutes (e.g., about 3-5 minutes). In some embodiments, electron conductor layer 16 may be a film having a thickness of about 1-10 micrometers. The method may include providing a quantum dot chemical bath deposition solution (which may include CdSe, for example) in a suitable vessel or bottle. The chemical bath deposition solution may have a concentration (e.g., a concentration of CdSe, for example) of, for example, about 26.7 mmol/L. This is just an example, and it is contemplated that any suitable concentration may be used. The temperature of the quantum dot chemical bath deposition solution may be controlled to a temperature of about 10° C. or greater, to a temperature of about 30° C. or greater, to a temperature within the range of about 10-60° C., to a temperature within the range of about 30-60° C., or to a temperature within the range of about 30-50° C. This may include placing the chemical bath deposition solution (or rather the vessel containing the chemical bath deposition solution) in a thermostat controlled water bath, but this is not required. The electron conductor layer 16 may be immersed in the quantum dot chemical bath deposition solution for about 0.5-10 hours, or for about 1-10 hours, or for about 70-600 minutes, or for about 70-200 minutes. In some embodiments, the immersing step may occur prior to the controlling step. In other words, electron conductor layer 16 may be immersed in the chemical bath deposition solution prior to controlling the temperature of the chemical bath deposition solution, during, or after.

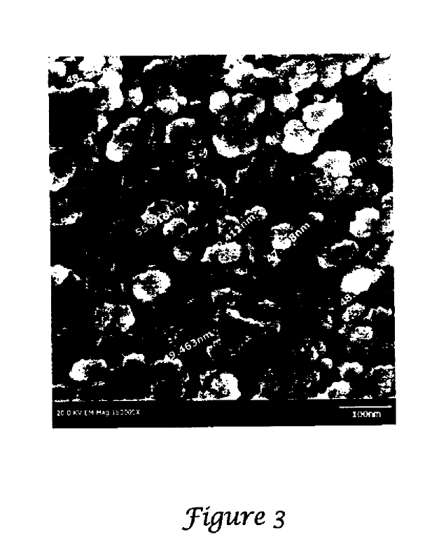

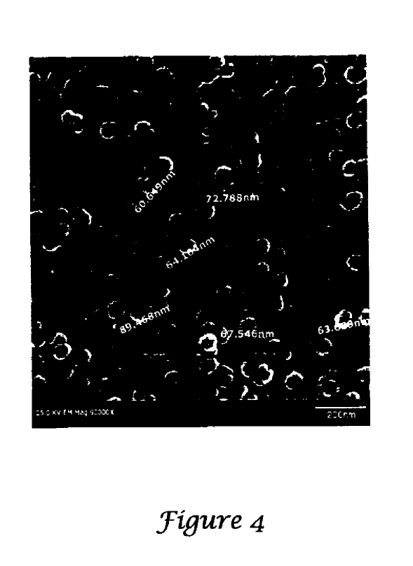

This illustrative method may be used to form a quantum dot layer 12 that has an enhanced efficiency. For example, the quantum dots shown in FIG. 3 have an average outer dimension of 50 nanometers. Quantum dots such as these may produce an absorption edge (e.g., the effective maximum wavelength or “edge” of the spectrum to which such quantum dots are substantially sensitive) of about 590 nanometers. The quantum dots shown in FIG. 4 have an average outer dimension of 65 nanometers. Quantum dots such as these may produce an absorption edge (e.g., the maximum wavelength or “edge” of the spectrum to which such quantum dots are sensitive) of about 650 nanometers. In general, quantum dot layer 12 may include quantum dots that have an average outer dimension greater than about 50 nanometers, or greater than about 50 nanometers to about 200 nanometers, or greater than about 50 nanometers to about 75 nanometers, or about 65 nanometers.

Because of the size of the quantum dots may be controlled, the absorption edge may be controlled and/or widened, which may enhance the overall efficiency of quantum dot layer 12 and, thus, solar cell 10. The short circuit current density produced by the solar cell may also be enhanced.

### EXAMPLES

The following examples serve to exemplify some illustrative embodiments, and are not meant to be limiting in any way.

### Example 1

Five sample quantum dot layers were prepared according to the chemical bath deposition method described above, with the noted temperature, time, pH and concentration levels indicated in Table 1 below. The short circuit current densities were measured for each sample, and the results are listed.

TABLE 1
Short Circuit Current Densities for Example Quantum Dot Layers

| Sample | | | | | |
|---|---|---|---|---|---|
| No. | Temperature¹ | Time² | pH | Concentration³ | Jsc⁴ |
| 1 | 10 | 600 | 10.5 | 26.67 | 8.886 |
| 2 | 30 | 200 | 10.5 | 26.67 | 9.222 |
| 3 | 40 | 140 | 10.5 | 26.67 | 9.795 |
| 4 | 50 | 100 | 10.5 | 26.67 | 10.284 |
| 5 | 60 | 70 | 10.5 | 26.67 | 8.360 |

¹Temperature of the chemical bath deposition solution, ° C.
²Immersion time in the chemical bath deposition solution, minutes.
³Concentration of CdSe in the chemical bath deposition solution, mM.
⁴Short circuit current density, mA/cm².

The average size of the quantum dots in a sample increased as the temperature used in the manufacture of the quantum dots increased. In sample 5, it is believed that the size of the quantum dots got too large to fit in the pores of the nanoporous TiO2 of the electron conductor film that was used, resulting in lower Jsc. This could be corrected by using an electron conductor film that has an increased pore size for sample 5, if desired.
In any event, the results show that, generally, the short circuit current density of the solar cell 20 increased as the temperature of the chemical bath deposition solution used for the quantum dot layer increased (e.g., comparing samples 2-4 to sample 1). Also, the UV-Visible absorption spectrum of the above quantum dot sample layers 1-4 increased as the temperature used is increased (e.g., comparing Samples Nos. 2-4 to Sample No. 1). Immersion time also impacted the absorption edge.

### Example 2

The performance of quantum dot solar cells using samples 1 and 2 above were also measured. Sample No. 1 was prepared via the chemical bath deposition method described above, where the chemical bath deposition solution was at 10° C. and the immersion time was 10 hours (600 minutes). Sample No. 2 was prepared via the chemical bath deposition method described above where the chemical bath deposition solution was at 30° C. and the immersion time was 200 minutes. The measured performance results are shown in Table 2.

TABLE 2
Performance of Example Solar Cells

| Sample | | | | | Rs (0.8 | Rs | |
|---|---|---|---|---|---|---|---|
| No. | Voc⁵ | Jsc⁶ | FF⁷ | η⁸ | V)⁹ | (Voc)¹⁰ | Rsh¹¹ |
| 1 | 0.563 | 8.886 | 0.556 | 3.031 | 39 | 74 | 11394 |
| 2 | 0.601 | 9.222 | 0.591 | 3.563 | 39 | 68 | 8980 |

⁵Open circuit voltage, V.
⁶Short circuit current density, mA/cm².
⁷Fill factor
⁸Conversion efficiency, %.
⁹Series resistance at 0.8 V, ohms.
¹⁰Series resistance at Voc, ohms.
¹¹Shunt resistance, ohms.

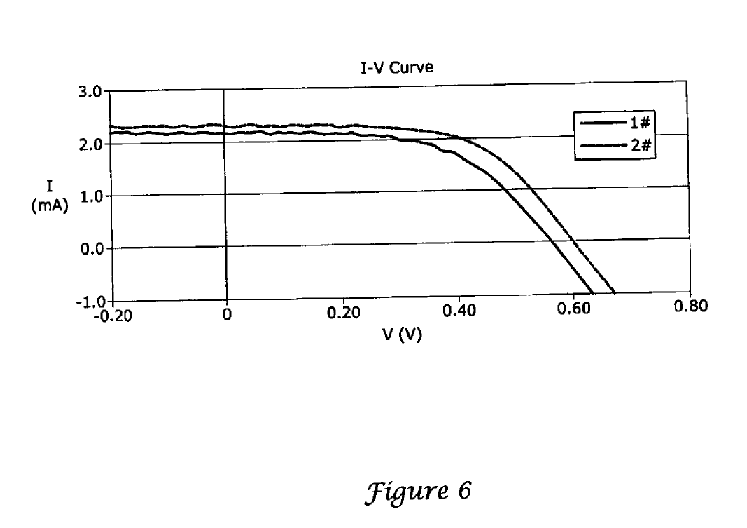

The results were measured using a 0.25 mm² mask and AM1.5 (e.g., full light spectrum). A plot of current (I) versus voltage (V) for Sample Nos. 1 and 2 is shown as FIG. 6. Here it can be seen that the current (I) produced by Sample 2, across a range of voltages (V), was greater than that of Sample 1.

It should be understood that this disclosure, in many respects, is only illustrative. Changes may be made in details, particularly in matters of shape, size, and arrangement of steps without exceeding the scope of the invention. The invention's scope is, of course, defined in the language in which the appended claims are expressed.

What is claimed is:

1. A method for manufacturing a quantum dot layer for a solar cell, the method comprising:
providing an electron conductor layer;
providing a quantum dot chemical bath deposition solution, the quantum dot chemical bath deposition solution including CdSe;
controlling the temperature of the quantum dot chemical bath deposition solution to a temperature of about 30° C. or greater; and
immersing the electron conductor layer in the quantum dot chemical bath deposition solution for about 1-10 hours.

2. The method of claim 1, wherein controlling the temperature of the quantum dot chemical bath deposition solution to a temperature of about 30° C. or greater includes controlling the temperature of the quantum dot chemical bath deposition solution to a temperature that is between about 30-60° C.

3. The method of claim 1, immersing the electron conductor layer in the quantum dot chemical bath deposition solution for about 1-10 hours includes immersing the electron conductor layer in the quantum dot chemical bath deposition solution for about 70-200 minutes.

4. A method for manufacturing a solar cell, the method comprising:
providing an electron conductor layer;
providing a quantum dot chemical bath deposition solution, the quantum dot chemical bath deposition solution including CdSe;
controlling the temperature of the quantum dot chemical bath deposition solution to a temperature of about 30° C. or greater;
immersing the electron conductor layer in the quantum dot chemical bath deposition solution for about 1-10 hours to form a quantum dot layer on the electron conductor layer;
providing a hole conductor layer; and
coupling the hole conductor layer to the quantum dot layer.

5. The method of claim 4, wherein the quantum dot layer includes a plurality of quantum dots having an average outer dimension greater than about 50 nanometers.

6. The method of claim 5, wherein the plurality of quantum dots have an average outer dimension greater than about 50 nanometers to about 200 nanometers.

7. The method of claim 5, wherein the plurality of quantum dots have an average outer dimension greater than about 50 nanometers to about 75 nanometers.

8. The method of claim 5, wherein the plurality of quantum dots have an average outer dimension of about 65 nanometers.

9. The method of claim 4, wherein the solar cell produces a short circuit current density of between about 9 to about 10.5 mA/cm².

10. The method of claim 4, wherein the solar cell produces a short circuit current density of about 9.222 to about 10.284 mA/cm².

11. The method of claim 4, wherein the quantum dot layer has an absorption edge greater than about 590 nanometers.

12. The method of claim 4, wherein the quantum dot layer has an absorption edge of between about 590 to about 650 nanometers.

13. A quantum dot solar cell, comprising:
an electron conductor layer;
a hole conductor layer; and
a quantum dot layer disposed between the electron conductor layer and the hole conductor layer, wherein the quantum dot layer includes CdSe and includes a plurality of quantum dots having an average outer dimension greater than about 50 nanometers.

14. The quantum dot solar cell of claim 13, wherein the solar cell has a short circuit current density between about 9 to about 10.5 mA/cm².

15. The quantum dot solar cell of claim 13, wherein the solar cell has a short circuit current density between about 9.222 to about 10.284 mA/cm².

16. The quantum dot solar cell of claim 13, wherein the plurality of quantum dots have an average outer dimension in the range of about 50 nanometers to about 200 nanometers.

17. The quantum dot solar cell of claim 13, wherein the plurality of quantum dots have an average outer dimension in the range of about 50 nanometers to about 75 nanometers.

18. The quantum dot solar cell of claim 13, wherein the plurality of quantum dots have an average outer dimension of about 65 nanometers.

19. The quantum dot solar cell of claim 13, wherein the quantum dot layer has an absorption edge that is greater than about 590 nanometers.

20. The quantum dot solar cell of claim 13, wherein the quantum dot layer has an absorption edge that falls between 590-650 nm.
